(19) United States
(12) Patent Application Publication
(10) Pub. No.: US 2007/0264819 A1
(43) Pub. Date: Nov. 15, 2007

(54) Method of forming an electrical isolation associated with a wiring level on a semiconductor wafer

(76) Inventors: Dirk Offenberg, Dresden (DE); Mirko Vogt, Dresden (DE); Hans-Peter Sperlich, Dresden (DE); Jean Charles Cigal, Dresden (DE)

Correspondence Address: SLATER & MATSIL LLP, 17950 PRESTON ROAD, SUITE 1000, DALLAS, TX, 75252, US

(21) Appl. No.: 11/280,802

(22) Filed: Nov. 16, 2005

Related U.S. Application Data
(63) Continuation-in-part of application No. 11/246,916, filed on Oct. 7, 2005.

(51) Int. Cl. H01L 21/4763

(52) U.S. Cl. 438/623; 438/622; 257/E21.495; 257/E21.496

(57) ABSTRACT

A method of forming a wiring level and an electrical isolation associated with the wiring level on a surface of a semiconductor wafer comprises the steps of providing the semiconductor wafer having said surface, forming a plurality of electrically conductive wiring lines upon said surface, each of the wiring lines having a spacing with respect to neighboring one of the wiring lines, depositing a first layer of amorphous carbon upon the wiring lines by means of non-conformal plasma enhanced chemical vapor deposition (PECVD), such that air-filled voids formed below the first layer within the spacings between neighboring wiring lines. Alternatively, OSG (organo-silicon glass) or FSG (fluorine doped silicon glass) may be deposited to yield air-filled voids within the spacings. According to an embodiment, the carbon, OSG or FSG layers are used as an IMD-layer (line-to-line isolation), added by a further layer of a dielectric material, which then serves as an ILD-layer (level-to-level isolation).

This application is a continuation-in-part of patent application serial number 11/246,916, entitled “Method of Forming an Electrical Isolation Associated with a Wiring Level on a Semiconductor Wafer,” filed on Oct. 7, 2005, which application is incorporated herein by reference.

### TECHNICAL FIELD

The invention generally relates to manufacturing integrated circuits, and to manufacturing semiconductor wafers. In particular embodiments, the invention particularly relates to the formation of a wiring level and an electrical isolation associated with the wiring level on a semiconductor wafer.

### BACKGROUND

In the field of manufacturing integrated circuits the process of forming conductive wiring levels, particularly metal levels, above a semiconductor substrate may be distinguished from the earlier formation of those electrical components, that depend on the presence of active areas within the monocrystalline silicon substrate. The corresponding process sequence aimed at the formation of those upper levels is thus also called “back-end of line” (BEOL). It comprises steps of forming wiring lines of a level, isolation layers between them and contacts in order to establish the desired connections between different wiring levels according the design of the integrated circuit to be manufactured.

As the integration level not only of the electrical components that are based on active areas increases, but also of the upper wiring levels, the electromagnetic interactions between the wiring lines have to be kept as small as possible in order to guarantee accurate functioning of the integrated circuit. This is particularly valid in the case of semiconductor memory products, wherein, for example, densely arranged bit lines form a first wiring level above the substrate (DRAM memory, dynamic random access memory). Consequently, an isolation between the wiring lines has to be provided, which minimizes among others the capacitive or inductive coupling between each two lines. The reduction of this coupling may be achieved by filling up the spacings between neighboring lines with a dielectric material, which has a low dielectric constant k.

Several low-k materials are known, but the corresponding process integration requires large efforts and costs. An alternative is to form voids within a dielectric layer, wherein the material deposited relates to conventional dielectrics having dielectric constants ranging from, e.g., 3.5 up to 4.5. A typical interlayer dielectric material is a silicon oxide having a dielectric constant k of around 4.0. The mean dielectric constant k of the layer may, however, be reduced by means of the voids, which are filled with air that has a constant k close to 1.

Interlevel (ILD) dielectric layers may be deposited upon the wiring lines of a wiring level in order to fill the spacings between the lines as well as to provide a separation between the next upper or lower wiring level. A common process to deposit dielectric materials for the ILD is high-density plasma deposition (HDP). HDP deposition is performed by means of a plasma reactor, which has in addition to a first plasma-generating high frequency source, a second high frequency source, which may be controlled separately from the plasma-generating source. This separate control may serve to direct and adjust the acceleration of high energy ions as a sputtering agent onto the target surface. Simultaneously the reactive species to be deposited on the target surface are supplied from the plasma. A hat-like profile results from this process. The capability of HDP for void-free filling is a function of the aspect ratio of the structures to be filled.

An advantage of HDP deposition arises from the fact that vertical walls of a deposition profile are more efficiently affected by the sputtering than horizontal surfaces. This is the reason why HDP deposition has been preferred over conventional plasma-enhanced CVD (PECVD: plasma enhanced chemical vapor deposition), since the deposition profile of PECVD-layers develops disadvantageous overhang sections due to the stronger growth of deposited material on horizontal surfaces as compared with vertical surfaces of structures on the wafer. The space beneath such an overhang effects a reduced ability to be accessed by further deposition, etc. Further, the overhangs reveal an increased roughness at the surface. Performing HDP deposition the overhangs cannot develop.

### SUMMARY OF THE INVENTION

In various embodiments, the present invention reduces the effects of capacitive or inductive coupling between wiring or metal lines of a wiring level of integrated circuits. A more particular embodiment reduces the mean dielectric constant k of the filling between different wiring levels. Further embodiments improve the manufacturing process and the quality of back-end of line (BEOL) process steps.

For example, one embodiment method forms a wiring level and an electrical isolation associated with a wiring level on a surface of a semiconductor wafer. At least two electrically conductive wiring lines are formed upon the surface of the wafer such that each two of the wiring lines encompass a spacing arranged there between. A first layer of a first dielectric material is deposited upon the wiring lines and into the spacings by means of plasma enhanced chemical vapor deposition (PECVD) such that air-filled voids form in the first layer within the spacings between neighboring wiring lines.

In another embodiment, a wiring level and an electrical isolation associated with the wiring level are formed on a surface of a semiconductor wafer. At least two electrically conductive wiring lines are formed upon the surface such that each two of the wiring lines encompass a spacing arranged there between. A first layer of amorphous carbon is deposited upon the wiring lines by means of a plasma enhanced chemical vapor deposition (PECVD), such that air-filled voids form below the first layer within the spacings between neighboring wiring lines.

According to embodiments of the invention, a plasma enhanced chemical vapor deposition (PECVD) is used to deposit dielectric material upon and, according to one aspect, between wiring lines of a wiring level. The deposition is performed, such that voids form between the wiring lines, i.e., within the spacings of those lines. The formation of voids is achieved by a suitable choice of parameter settings during deposition and depends on the particular apparatus employed for the deposition process.

It is noted that the HDP deposition also refers to a plasma enhanced CVD process. However, according to embodiments no sputtering is performed with respect to PECVD process as disclosed herein. This means that no HDP deposition is performed in such embodiments with respect to the deposition of the first layer. The formation of voids, which are air-filled, leads to a reduction of the mean dielectric constant k of the first layer. More explicitly, a dielectric constant k close to 1 of air may reduce the mean dielectric constant to values of less than 3.2, as an example.

Further, it has been found that the PECVD process, if adapted to form voids within spacings by means of the deposition parameter settings, may be controlled such that a target geometry, size and position of the voids within the spacings can be maintained up to a considerable degree.

In contrast, an HDP deposition may be adapted to form voids, but the voids thus formed are found to be hardly controllable. For example, the sizes of those voids may vary from spacing to spacing despite the depths and widths of those spacings between neighboring being similar. The same is similar with respect to position and geometry of those voids. In particular, voids as formed by HDP deposition may be located in undesired locations above a spacing, where a further CMP (chemical mechanical polishing) process may result in opening the void. A further deposition process, for example of a metal, may then lead to a malfunction of the resulting circuit. According to the invention, however, the voids may be well-controlled by the process parameter settings and the void characteristics are highly reproducible.

A preferred embodiment relates to forming voids by depositing amorphous carbon as the first layer. A highly non-conformal carbon deposition results in the formation of voids, which in this case fill up the complete spacing between two wiring lines. This means, that upon deposition of amorphous carbon as the first layer, the spacings may be kept free from amorphous carbon, which again yields a particularly low k value for these spacings. The reason is that amorphous carbon provides the feature, that under optimum parameter settings of the plasma reactor, the growth is directed merely upwards from horizontal surfaces, while vertical surfaces may be kept free from any deposition. In a PECVD carbon deposition process, the most inclined direction of growth, as measured from the normal axis, amounts to a maximum of 40°, or a minimum of 50° with respect to an idealized horizontal surface plane of the wafer.

It is found that leakage currents and breakdown voltages of air gaps are uncritical for the BEOL process applications as being considered herein.

Alternative embodiments relate to employing fluorine or carbon doped silicon glass as the dielectric material for the first layer. It is found that both materials may be advantageously employed in combination with the PECVD process yielding highly reproducible and conformal voids. In particular, the voids thus formed reside within the spacing, hardly extending out from this spacing into a region above it, which otherwise might lead to an interference with the next upper wiring level as explained above.

A further aspect of the invention relates to applying a second layer comprising a second dielectric material in addition to the first layer. Accordingly, the electrical isolation of the wiring level is provided by two different dielectric layers. Therein, the first layer formed by a PECVD process, which includes or leads to the formation of voids, mainly represents a so-called intrametal dielectric (IMD) layer. This layer serves to reduce capacitive and/or inductive coupling between wiring lines of the same wiring level. The second layer is provided as an interlevel dielectric (ILD) layer, which serves to reduce the capacitive and/or inductive coupling from wiring lines of one wiring level with respect to wirings lines of another wiring level.

In an alternate embodiment, a second layer comprising a second dielectric material is applied upon the first dielectric layer in order to yield a final passivation layer on top of a layer stack, which is formed upon a semiconductor wafer. This passivation layer serves to protect the chip underneath against mechanical or thermal stress. As this layer typically provides the uppermost layer on the substrate, no further metal layer is formed upon the passivation layer, disregarding possible wirings within a plastic chip housing, which may enclose the chip, and which may be bonded to the chip.

Passivation layers according to embodiments of the invention may include a two layer stack. Preferrably, the bottom layer is formed from one of fluorine-doped or carbon-doped silicon glass, or amorphous carbon. These are directly applied upon the metal wiring by means of a PECVD process, wherein air filled voids form inbetween the spacings of the metal wiring. In the case of amorphous carbon, the voids may fill the spacings completely due to the inclined growth signature of the PECVD carbon deposition as explained above. Above this, a second layer of silicon nitride is deposited as the uppermost layer. Silicon nitride has a significantly larger dielectric constant of 7-8 as compared with, e.g., silicon oxide. However, as there is no further metal layer, capacitive coupling beyond this second dielectric layer only plays a minor role.

In a further embodiment relating to passivation layers, this layer may be constructed from amorphous carbon, solely. Herein, amorphous carbon is considered to provide both the air filled voids along with the ability to protect the chip underneath from mechanical or thermal influences.

Referring back to ILD layers, in a preferred embodiment, the dielectric materials are chosen differently, such that the second layer (ILD) may serve as a hard mask with respect to etching the first layer (IMD) in order to form contacts between wiring lines of different wiring levels.

In one embodiment, the second layer may be a silicon oxide, or fluorine-doped or carbon-doped silicon glass, and the first layer is made of amorphous carbon. The silicon glass or oxide layer may serve as a hard mask for etching the carbon. This feature provides an accurate etch profile with respect to carbon on the one hand, and further the existence of a protection layer (silicon glass or oxide) with regard to amorphous carbon on the other hand. Amorphous carbon could be harmed when a further metal, for example tungsten, is deposited directly upon the carbon layer, because of the comparatively high temperatures applied during such a deposition.

With regard to the formation of wiring lines of the wiring level, the invention is not limited to sets of explicit steps as embodied herein. The formation of wiring levels starts with the provision of a wafer having a preferably plane surface. The surface can be planarized by means of, e.g., chemical mechanical polishing (CMP). The surface may relate to the substrate surface (silicon) or an isolation layer of a next lower wiring level.

For example, wiring lines may be formed by first depositing a sacrificial material, which will be removed later. The layer of this sacrificial material is then patterned using resist techniques. Removed portions of the pattern within this layer are filled with electrically conductive material, e.g., a metal such as tungsten, aluminum, copper or compositions comprising these materials, e.g., tungsten silicide. Planarizing the conductive layer back to the surface of the sacrificial layer restricts the conductive material to the removed portions within the layer of the sacrificial material. The remainder of the latter is also removed such that conductive wiring lines remain as raised structure elements upon the substrate surface.

Alternatively, the conductive material can be deposited upon the planarized surface of the isolation layer and be lithographically patterned to yield the wiring lines, for example.

### BRIEF DESCRIPTION OF THE DRAWINGS

Other aspects and many of the attendant advantages of embodiments of the present invention will be readily appreciated and become better understood by reference to the following more detailed description of preferred embodiments in connection with the accompanied drawings. Features that are substantially or functionally equal or similar will be referred to with the same reference signs.

FIG. 1 shows a profile of wiring lines formed on a surface of a semiconductor wafer;

FIGS. 2-3 show further development of the profile as shown in FIG. 1 using HDP deposition including the formation of voids according to prior art;

FIGS. 4-7 show further development of the profile as shown in FIG. 1 using PECVD deposition of OSG (organosilicon glass) or FSG for forming an IMD layer, which includes voids, according to a first embodiment of the invention;

FIGS. 8-11 show further development of the profile as shown in FIG. 1 using PECVD deposition of amorphous carbon for forming an IMD layer, which includes voids, according to a second embodiment of the invention; and

FIGS. 12-15 show a sequence of process steps for forming a wiring level and its associated isolation by means of PECVD deposition of amorphous carbon and damascene technique according to a third embodiment of the invention.

FIG. 16 shows an embodiment of a passivation layer stack comprising a layer of PECVD deposited amorphous carbon and a layer of silicon nitride.

The following list of reference symbols can be used in conjunction with the figures:

| | |
|---|---|
| 10 | semiconductor wafer |
| 12 | isolation layer |
| 13 | surface |
| 14, 14a, 14b, 14c | wiring levels |
| 16, 16a, 16b, 16c | electrically conductive wiring lines |
| 18 | HDP deposition layer |
| 20 | hat-like surface topography |
| 22, 23, 210-213 | air-filled voids |
| 30 | spacings between wiring lines |
| 32 | outer edge of wiring field |
| 34 | CMP-target surface |
| 36 | PECVD deposition layer (OSG or FSG) for IMD |
| | and/or ILD |
| 38 | overhang |
| 39 | second layer (amorphous carbon serving as |
| | temporary hardmask) |
| 40 | back etch (OSG or FSG) |
| 41 | back etch (amorphous carbon) |
| 44 | hardmask openings |
| 46 | hardmask etch (OSG or FSG with respect to |
| | carbon hardmask) |
| 48, 49, 481 | PECVD deposition layer (amorphous carbon) for IMD |
| 482 | second layer (silicon nitride) for passivation |
| 50 | overhang |
| 52 | second layer (OSG, FSG or silicon oxide) for ILD |
| 54 | hardmask etch (carbon with respect to second layer) |
| 56 | hardmask openings |
| 58 | etched contact via |
| 102 | isolation layer of lower wiring level |
| 104 | etch stop layer |
| 106 | sacrificial layer of amorphous carbon |
| 108 | resist mask |
| 160 | contact via filled in damascene process |

### DETAILED DESCRIPTION OF ILLUSTRATIVE EMBODIMENTS

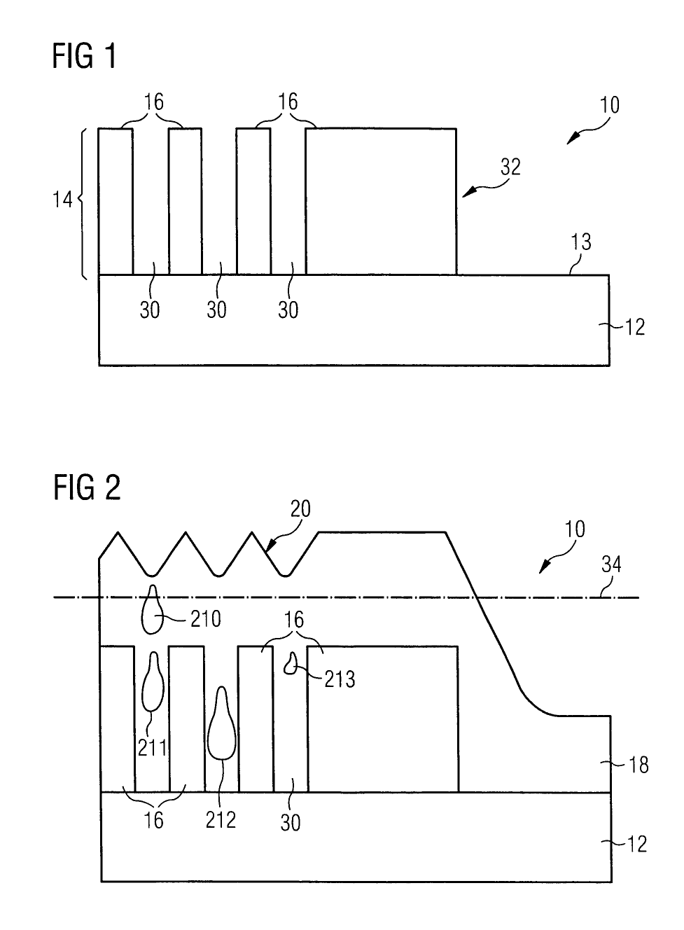

FIG. 1 shows a profile of raised structure elements arranged in parallel on a surface 13 of a semiconductor wafer 10. The raised structure elements are wiring lines 16, which correspond to a wiring level 14. Each two of the wiring lines 16 encompass spacings 30 formed in between the field of wiring lines. The outermost of the wiring lines 16 has an outer edge 32 oriented towards an area of the surface 13, which is not covered with wiring lines 16.

The surface 13 is provided by a planarized upper surface of an isolation layer 12, which pertains to a further wiring level arranged next below the present wiring level 14, and may contain a silicon oxide, a nitride, a doped silicon glass, etc. Alternatively, layer 12 may represent an isolation layer, which covers a silicon substrate (not shown).

The wiring lines 16 may comprise any electrically conductive material such as doped polysilicon or a metal, or a metal silicide, etc. It is further possible, that wiring lines 16 include stacks of electrically conductive layers as is the case with respect to word lines in a DRAM memory. Wiring lines 16 may also represent bit lines of such a memory.

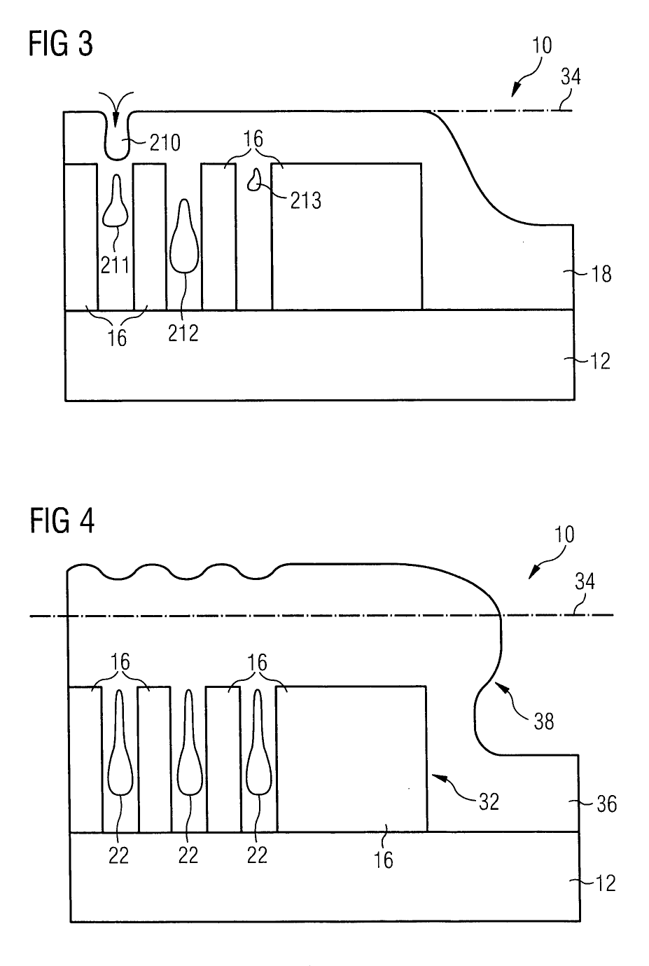

FIGS. 2-3 show a sequence of process steps evolving from the profile shown in FIG. 1, wherein a HDP deposition is performed to form an isolation layer 18. The deposition is continued until a sufficient thickness of layer 18 is achieved, such that a following CMP process may recess the surface to height level 34. What can be seen in FIG. 2 is the formation a surface profile comprising hats 20 typical for HDP deposition.

Further, voids 210-213 are formed, which are filled with air. The voids might decrease the mean dielectric constant of material within spacings 30. However, the voids are positioned irregularly and have different sizes. The amount of electromagnetic interaction between neighboring wiring lines 16 thus differs from line to line, decreasing the reliability of the integrated circuit.

FIG. 3 further illustrates the effect of applying a CMP process. One of the voids, i.e., void 210, is opened due to the recess, such that deposition of further material, e.g., metal of an upper wiring level, might lead to interactions with the wiring of the present level.

FIGS. 4-7 show a sequence of process steps according to an embodiment of the invention. Applying a PECVD deposition of organosilicon glass (OSG) or fluorine doped silicon glass (FSG) to the situation as indicated in FIG. 1 results in a layer 36 of dielectric material as shown in FIG. 4. Thereby, the PECVD plasma reactor is adjusted with regard to deposition parameter settings such that voids 22 are formed. The size and location of the voids 22 is regularly arranged and the voids reside well within the spacings 30 between neighboring wiring lines 16.

Further, at the outer edge 32 of the field of wiring lines 16, an overhang 38 comprising a disadvantageously rough surface develops. A first recess 40 of layer 36 is thus performed, which removes this overhang 38 as can be seen in FIG. 5. This etch back may be for example performed by HDP-etching (no deposition).

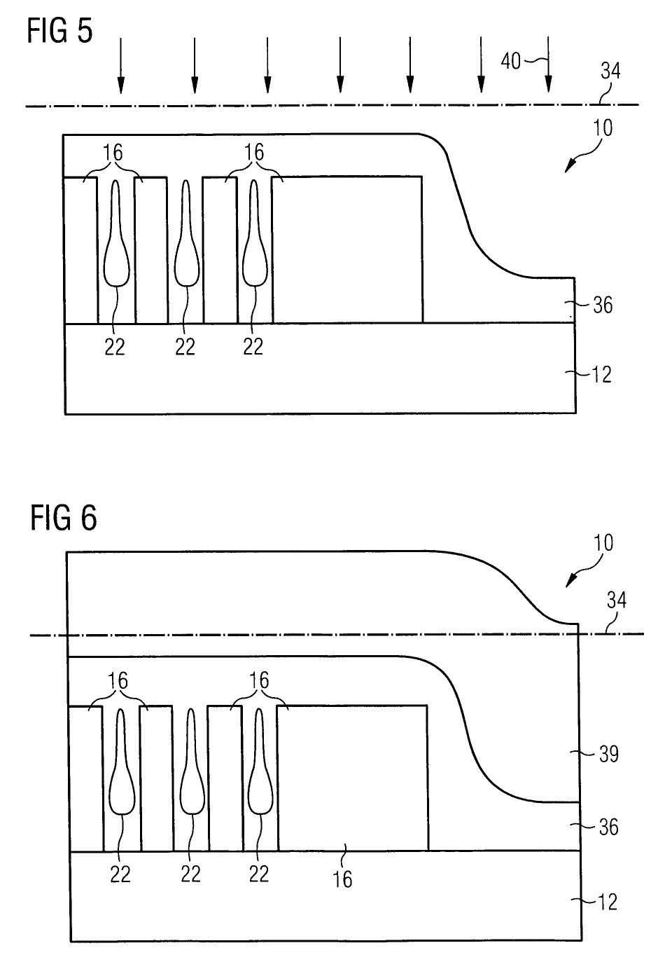

FIG. 6 shows the situation after deposition of a second layer 39 having a surface above the CMP-target surface 34. The second layer in this embodiment will additionally be used as a hardmask to etch contact holes into the first layer 36 of OSG or FSG. It thus comprises an etch selective material with respect to OSG or FSG, for example a nitride. In one alternative embodiment, this second layer 39 is formed from amorphous carbon, which, however, may be removed after being used as hardmask.

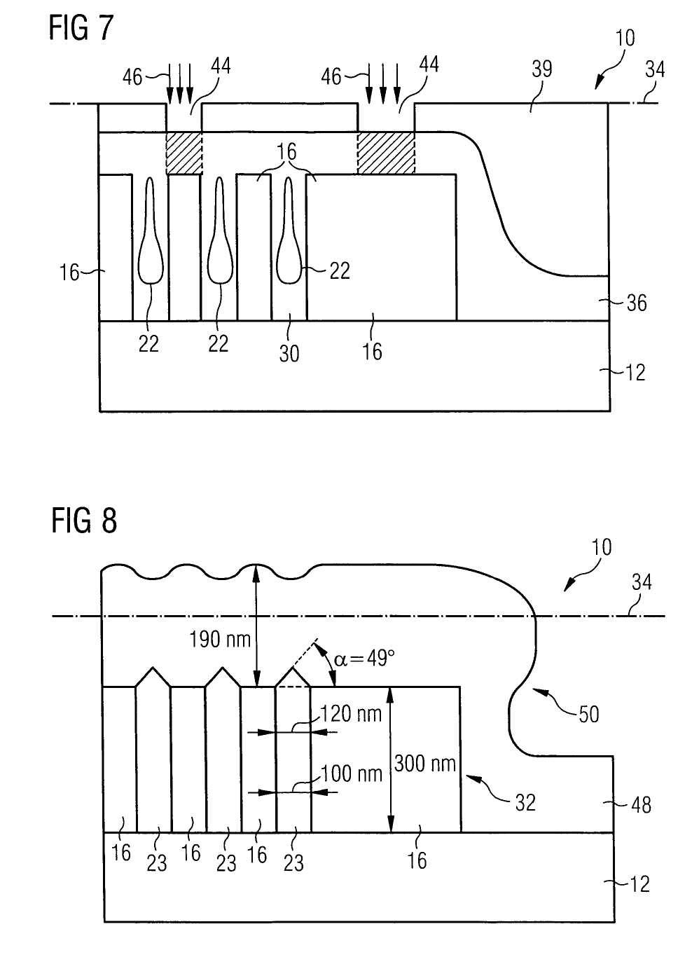

The hard mask etch 46 is illustrated in FIG. 7. Openings 44 in the hardmask layer 39 are already formed and the etch 46 affects those spaces indicated by the shadowed area in FIG. 7.

Another embodiment according to the invention is indicated in FIGS. 8-11. The sequence also starts from the profile of wiring lines 16 displayed in FIG. 1. In this embodiment, a PECVD deposition of amorphous carbon is performed to yield a first layer 48 (see FIG. 8). As in the previous example, no sputtering is applied during the deposition, i.e., the plasma reactor is driven with only one high frequency voltage source for generating the plasma.

The thickness of the deposited layer 48 of amorphous carbon in this example amounts to 190 nm. The growth behavior of amorphous carbon is almost directed upwards starting from horizontal surfaces, which are the top sections of the wiring lines 16 herein. The direction of growth deviates from a vertical axis by 40° to 70° in this embodiment at the edges of the horizontal surfaces. No growth can be seen at vertical sidewalls of the wiring lines, where there are large aspect ratios of the spacings 30 between the wiring lines. It is noted that the aspect ratio is less important here, rather the spacing between lines has a strong influence on whether the voids as shown in the figure may develop or not. In current technology nodes, the spacing between raised lines may amount to less than 150 nm, which makes it suitable for air gap formation according to embodiments of the invention.

The upwards directed growth behavior leads to the formation of voids 23 within the spacings 30. The voids 23 differ from those voids provided in the previous examples in that the spacings 30 are nearly completely kept free of any deposition material as long as the aspect ratios are sufficiently large or the width of the spacings alone amounts to less than 170-200 nm.

The deposition of amorphous carbon by means of PECVD deposition is known from U.S. Pat. No. 6,573,030 B1, to Applied Materials, Inc., Santa Clara, Calif., which is incorporated herein by reference, for the purpose of manufacturing an antireflex coating or a temporary hard mask. As described therein, a layer of amorphous carbon may be formed from a mixture of a hydrocarbon compound and an added inert gas (He or Ar). The hydrocarbon compound may be expressed as CₓH_{y}, wherein x ranges from 2 to 4, and y ranges from 2 to 10, for the compounds considered therein. An example is propylene C₃H₆. Ar, He or N₂ are added to control the density and deposition rate of the amorphous carbon layer.

In the document cited, the following process parameters are suggested—among others—to form the layer of amorphous carbon in a PECVD process:

| | |
|---|---|
| Wafer temperature: | 100°-500° C. |
| Chamber pressure: | 1-20 Torr |
| Gas flow: | 50-500 sccm |
| RF power: | 3-20 W/in². |

The parameter ranges recited herein are provided for illustration purposes only, and the invention is, however, not limited to these parameter ranges as specified above. The ranges may further depend on the specific plasma reactor, which has been used.

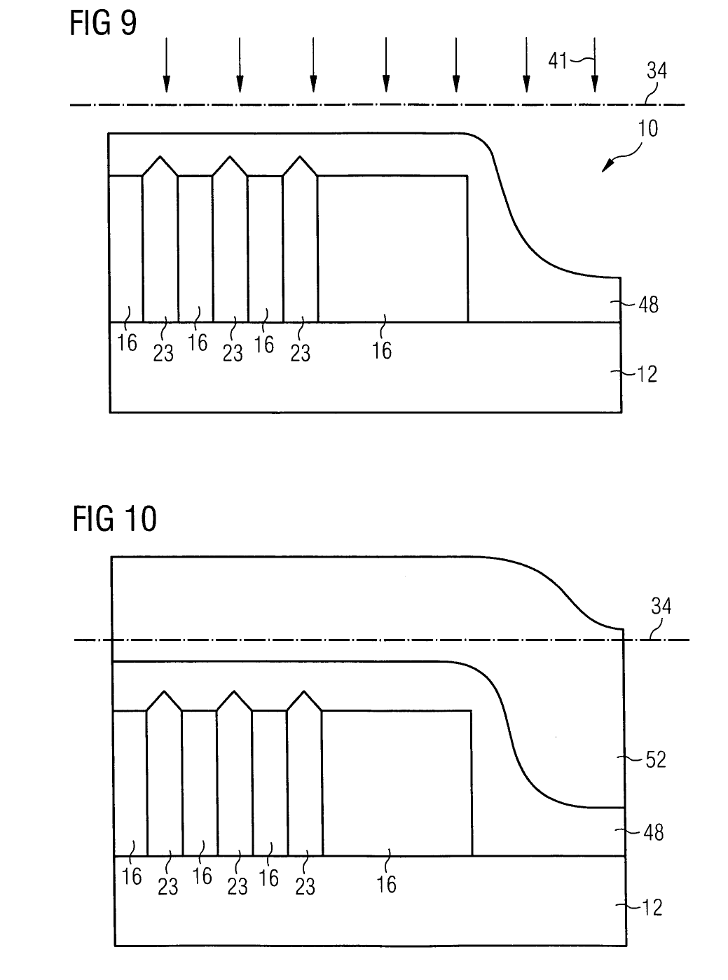

In a next step, as shown in FIG. 9, an optional recess of the first layer 48 of amorphous carbon is performed by means of a back etch 41 using H₂. The same plasma reactor may be used for the PECVD deposition and the back etch 41. In this etch back process, the overhang 50 due to the PECVD deposition at the outer edge of the wiring line field is efficiently removed.

FIG. 10 shows the situation after deposition of a second layer 52 of dielectric material, which may be, for example, FSG or OSG. The thickness applied is such that the target surface for the CMP to be performed subsequently falls below the surface of the second layer 52. It is noted that the isolation associated with the wiring level is essentially a bilayer isolation formed from the first layer 48 as an IMD-layer and the second layer 52 as an ILD layer. Since the increase of integration has a stronger effect on line-to-line distances than to level-to-level distances, the requirements with regard to the intrametal dielectric have equally been found to be stronger. Thus, the efforts spent in forming the first layer 48 of amorphous carbon may be reduced to the IMD-layer.

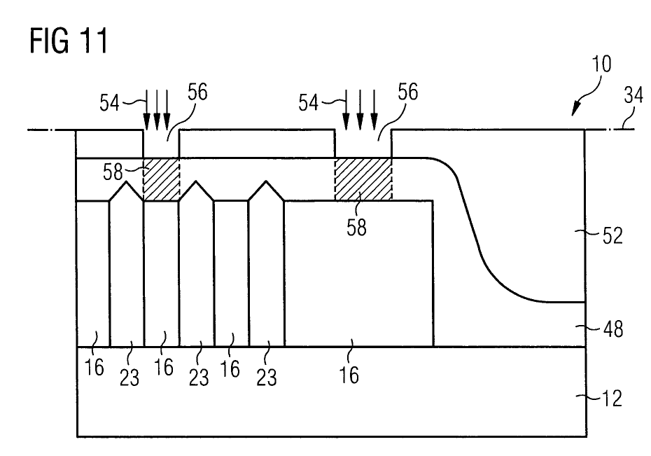

FIG. 11 illustrates the further use of the second layer 52 as a hardmask. An etch 54 of the layer 48 of amorphous carbon is performed in the hardmask openings 56 with respect to second layer 52. Portions are thus removed from the first layer 48 in order to yield contact holes 58. The next upper wiring level may then be formed in a damascene process, for example.

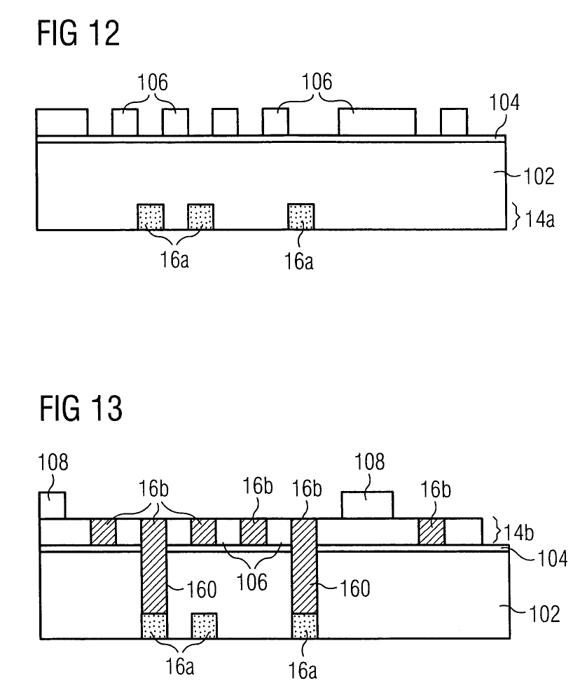

A third embodiment is shown in the sequence of FIGS. 12-15. FIG. 12 illustrates a first wiring level 14a with wiring lines 16a, which has already been finished including its associated isolation 102. An thin etch stop layer 104 is deposited thereupon along with a sacrificial, or temporary layer 106 of amorphous carbon. The layer 106 is lithographically patterned, such that portions are removed, which define the wiring of the wiring level 14b to be formed next.

FIG. 13 shows the situation after etching vias into the isolation layer 102 in order to form contacts 160 between the wiring levels 14a, 14b, and after deposition of a conductive material, for example a metal such as aluminum, tungsten or copper or a composition comprising such a material. The deposition followed by a planarization, e.g., CMP, refers to a damascene process. Further, a block mask 108 is applied to define portions or spacings between the wiring lines 16b with the deposition, which cannot be filled with voids, since their width may be too large.

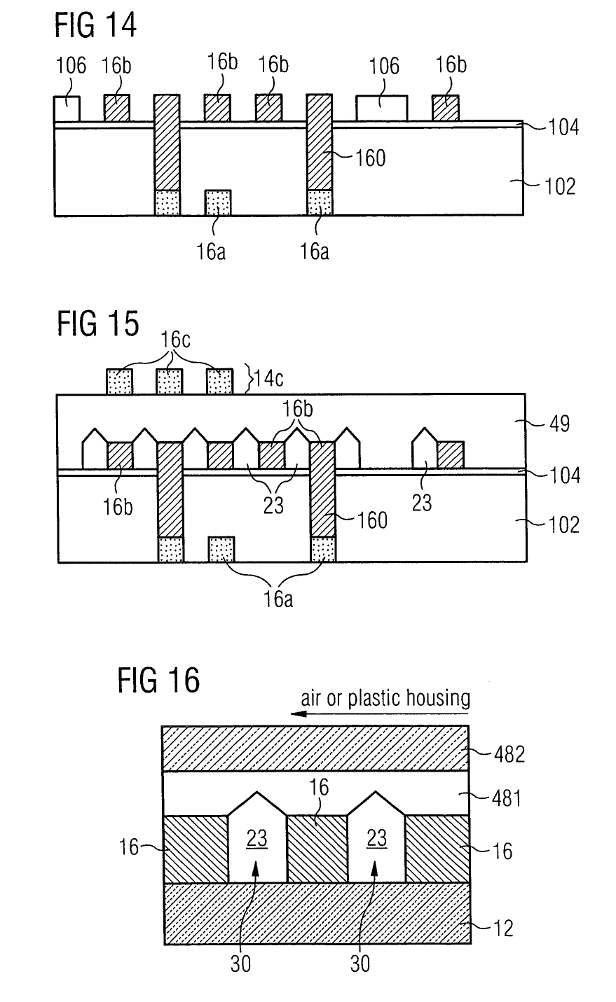

FIG. 14 shows the situation after unblocked portions of the sacrificial layer 106 of amorphous carbon have been removed in an etch process.

FIG. 15 illustrates the formation of voids by a repeated deposition of layer 49 of amorphous carbon in a PECVD process. A next wiring level 14c, which includes wiring lines 16c may then be formed.

FIG. 16 shows an embodiment relating to the formation of a final passivation layer. An isolation layer 12 referring to an underlying metallization layer has a (preferably) planarized surface. Upon this surface, multiple wiring lines 16 of an uppermost metallization layer with regard to an integrated circuit are formed in a lithographic patterning process. The wiring lines 16 are formed as raised structures upon the surface and a spacing 30 is enclosed between each two of the wiring lines 16.

In a process similar to that shown in FIG. 8, a layer 481 of amorphous carbon is deposited in a PECVD process in order to yield air-filed voids 23 within the spacings 30. Due to the inclined growth property of this process, the spacings 30 are overgrown by the amorphous carbon layer 481 and are thus substantially kept free of any material other than air (i.e., the low pressure gas residing in the PECVD chamber during the deposition process). In other words, the sidewalls of the wiring lines do not undergo a deposition of carbon material.

The layer 481 of amorphous carbon is then planarized, e.g., polished or recessed by etching, etc. Thereafter, a further dielectric layer 482 of silicon nitride is deposited on the carbon layer 481. Accordingly, the final passivation layer according to this embodiment is represented by a two-layer stack of amorphous carbon and silicon nitride. The former layer provides the air-filled voids in order to decrease capacitive coupling between the wiring lines 16, and the latter provides the mechanical and thermal protection. In the case of DRAM or other memory products, the chip being finished by the passivation layer may be enclosed in a plastic housing to yield a package. In other cases, the passivation layer may remain as the outermost protection of the chip.

In another embodiment, not shown in the figures, the passivation layer may be provided by the layer 481 of amorphous carbon, alone. That is, no further layer (e.g., dielectric layer 482) is applied to the carbon layer, which then serves as the outermost layer of the chip.

As a result of these embodiments, a lowest possible mean coupling is achieved by the air-filled voids. In prior art passivation layers, which may comprise stacks of silicon oxide serving as an IMD and of silicon nitride serving as a passivation means, it was even possible that silicon nitride reached into the spacings between wiring lines, which yielded a considerably enhanced capacitive coupling between lines 16 of this uppermost conductive wiring level.

Although the present invention and its advantages have been described in detail, it should be understood that various changes, substitutions and alterations can be made herein without departing from the spirit and scope of the invention as defined by the appended claims.

1. A method of forming a wiring level and an electrical isolation associated with the wiring level on a surface of a semiconductor wafer, the method comprising:
providing a semiconductor wafer having a surface;
forming a plurality of electrically conductive wiring lines upon said surface, the wiring lines having a spacing with respect to neighboring ones of the wiring lines;
depositing a first layer of a first dielectric material upon the wiring lines and into the spacings by means of plasma enhanced chemical vapor deposition (PECVD), wherein the deposition is performed non-conformally such that air-filled voids form in the first layer within the spacings between neighboring wiring lines;
depositing a second layer upon the first layer to form a hardmask; and
etching through the first layer to form contact holes to one or more of the conductive wiring lines.

2. The method according to claim 1, wherein the first dielectric material deposited as the first layer comprises fluorine-doped silicon dioxide (FSG) or organo-silicon dioxide (OSG) or a combination of both.

3. The method according to claim 1, wherein the wiring lines are formed from aluminum, tungsten, or copper.

4. The method according to claim 1, wherein the plasma enhanced chemical vapor deposition is performed in a sputtering-free process.

5. The method according to claim 1, comprising the further step of recessing the first layer in order to remove an overhanging profile of the first layer at an outer edge of an arrangement of wiring lines.

6. The method according to claim 5, wherein the step of recessing the first layer includes a chemical mechanical polishing of the first layer.

7. The method according to claim 5, wherein the step of recessing the first layer includes etching back of the first layer.

8. The method according to claim 5, wherein the second layer is a second dielectric material that forms an interlevel dielectric.

9. The method according to claim 8, wherein the second dielectric material deposited as the second layer is at least one of fluorine-doped silicon dioxide (FSG), organo-silicon dioxide (OSG), a silicon oxide, a spin-on dielectric (SOD), silicon carbide or silicon nitride.

10. The method according to claim 9, comprising the further step of applying a chemical mechanical polishing (CMP) step after deposition of the second layer.

11. A method of forming a wiring level and an electrical isolation associated with the wiring level on a surface of a semiconductor wafer, the method comprising:
providing a semiconductor wafer having a surface;
forming a first plurality of electrically conductive wiring lines upon said surface, the wiring lines having a spacing with respect to neighboring ones of the wiring lines;
depositing a first layer of amorphous carbon upon the wiring lines by means of plasma enhanced chemical vapor deposition (PECVD), such that air-filled voids form below the first layer within the spacings between neighboring wiring lines; and
forming a second plurality of electrically conductive wiring lines upon said layer of amorphous carbon.

12. The method according to claim 11, wherein the deposition of the first layer is performed without sputtering.

13. The method according to claim 11, wherein the wiring lines are formed from aluminum, tungsten, or copper.

14. The method according to claim 11, comprising the further step of recessing the first layer in order to remove an overhanging profile of the first layer at an outer edge of an arrangement of wiring lines.

15. The method according to claim 14, wherein the step of recessing the first layer includes etching back of the first layer.

16. The method according to claim 15, wherein the step of etching back the first layer includes an etch back process using H₂, NH₃, B₂H₆, or O₂ as a reacting agent.

17. The method according to claim 16, wherein an etch back process using H₂ as a reacting agent is performed in-situ.

18. The method according to claim 11, comprising the further step of depositing a second layer of a second dielectric material upon the first layer to form an interlevel dielectric.

19. The method according to claim 18, wherein the second dielectric material deposited as the second layer is at least one of fluorine-doped silicon dioxide (FSG), organo-silicon dioxide (OSG) a silicon oxide, a spin-on dielectric (SOD), silicon carbide, or silicon nitride.

20. The method according to claim 18, comprising the further step of applying a chemical mechanical polishing (CMP) step after deposition of the second layer.

21. The method according to claim 11, comprising the further step of depositing a second layer of a second dielectric material over the first layer to form a final passivation layer of the semiconductor wafer.

22. The method according to claim 20, wherein depositing the second dielectric material includes depositing a silicon nitride.

23. The method according to claim 11, wherein the first dielectric layer of amorphous carbon is deposited as a final passivation layer of the semiconductor wafer.

24. The method according to claim 11, wherein
the wiring lines are formed from copper; and
a diffusion barrier is arranged between said copper of the wiring lines and said amorphous carbon of said first layer.

25. A semiconductor device, comprising:
a plurality of electrically conductive wiring lines disposed over a surface of a semiconductor wafer, wherein each wiring line has a spacing with respect to a neighboring one of the wiring lines;
a first layer of amorphous carbon deposited over the wiring lines, such that air-filled voids are formed within the spacings between neighboring wiring lines, wherein the sidewalls of the wiring lines do not undergo a deposition of carbon material; and
a second layer of a dielectric material deposited upon the first layer as a final passivation layer, wherein the second layer of a dielectric material comprises silicon nitride.

26. The semiconductor device according to claim 25, wherein the wiring lines comprise at least one of aluminum, tungsten and copper.

27.-31. (canceled)

32. A semiconductor device, comprising:
a plurality of electrically conductive wiring lines disposed over a surface of a semiconductor wafer, wherein each wiring line has a spacing with respect to a neighboring one of the wiring lines;
a first layer of a first dielectric material deposited upon the wiring lines and into the spacings, wherein the first layer is deposited non-conformally such that air-filled voids are formed in the first layer within the spacings between neighboring wiring lines;
a second layer of a dielectric material deposited upon the first layer as an interlayer dielectric (ILD); and
a further multiple of wiring lines of a next wiring level said wiring lines formed upon the second dielectric layer.

33. The semiconductor device according to claim 32, wherein the wiring lines comprise at least one of aluminum, tungsten and/or copper.

34. The semiconductor device according to claim 32, wherein first layer comprises fluorine-doped silicon dioxide (FSG) or organo-silicon dioxide (OSG) or a combination of both.

35. The semiconductor device according to claim 34, wherein the first layer comprises carbon-doped silicon oxide.

36. (canceled)

37. The semiconductor device according to claim 32, wherein the second layer is at least one of fluorine-doped silicon dioxide (FSG), organo-silicon dioxide (OSG), a silicon oxide, a spin-on dielectric (SOD), silicon carbide or silicon nitride.

38. (canceled)
